(19) United States
(12) Patent Application Publication
(10) Pub. No.: US 2017/0186866 A1
(43) Pub. Date: Jun. 29, 2017

(54) VERTICAL FIELD EFFECT TRANSISTOR HAVING A DISC SHAPED GATE

(71) Applicant: Skokie Swift Corporation, Silver Spring, MD (US)

(72) Inventor: Moshe Einav, Kfar Uriyah (IL)

(73) Assignee: Skokie Swift Corporation, Silver Spring, MD (US)

(21) Appl. No.: 15/127,229

(22) PCT Filed: Mar. 19, 2015
(86) PCT No.: PCT/IL2015/050292

§ 371 Date: Sep. 19, 2016

Related U.S. Application Data
(60) Provisional application No. 61/955,803, filed on Mar. 20, 2014.

(51) Int. Cl. H01L 29/78; H01L 29/10; H01L 29/417; H01L 29/66; H01L 21/283; H01L 29/423; H01L 29/08

(52) U.S. Cl. CPC H01L 29/7827; H01L 29/4236; H01L 29/1033; H01L 29/0847; H01L 29/66666; H01L 21/283; H01L 29/41741; H01L 29/41766

(57) ABSTRACT

A vertical FET, including a source layer, a channel layer, a drain layer and a gate dielectric, the source layer being coupled with a source electrode, the channel layer being deposited on top of the source layer, the drain layer being deposited on top of the channel layer and being coupled with a drain electrode, the gate dielectric being conformally deposited within a cylindrical niche through the drain layer down to the channel layer, the gate dielectric being encircled by the drain layer, the gate dielectric being coupled with a gate electrode deposited within the cylindrical niche, when a threshold voltage Is applied to the gate electrode a channel is formed between the source layer and the drain layer, a length of the channel corresponding to a thickness of the channel layer and a width of the channel corresponding to a perimeter of the cylindrical niche.

### FIELD OF THE DISCLOSED TECHNIQUE

The disclosed technique relates to an Insulated Gate Field Effect Transistor (IGFET) and a method of its manufacture, in general, and to methods and systems for producing a vertical FET having a disc-shaped gate, in particular.

### BACKGROUND OF THE DISCLOSED TECHNIQUE

A transistor a three terminal electronic component in which a voltage between two terminals is employed for controlling the current flowing in the third terminal. A transistor can therefore be embodied, for example, as an amplifier or a switch. An IGFET is a transistor in which the control of the current flowing to the aforementioned third terminal is based on an electric field produced by a voltage applied between the other two terminals.

Reference is now made to FIG. 1 which is a schematic Illustration of a Metal-Oxide Semiconductor FET (MOSFET), generally referenced 10, constructed and operative as known in the prior art. MOSFET 10 includes a P-type substrate 12 (also referred to as P-type body 12), an N-type source 14, an N-type drain 16, an oxide layer 18 (also referred to as a dielectric layer 18), a gate electrode 20, a source electrode 22 and a drain electrode 24, P-type body 12 (also referred to as merely body 12), N-type source 14 (also referred to as merely source 14) and N-type drain 16 (also referred to as merely drain 16) are differently doped regions of the same silicon wafer. In particular, source 14 and drain 16 are two N-type doped regions separated by a portion of P-type body 12, thereby producing two back-to-back PN junctions. Specifically, the boundary between source 14 and body 12 is an NP junction, and the boundary between body 12 and drain 16 is a PN junction.

Dielectric layer 18 covers the portion of body 12 between source 14 and drain 16 and also covers small portions of source 14 and of drain 16. Gate electrode 20 is coupled with dielectric layer 18, source electrode 22 is coupled with source 14 and drain electrode 24 is coupled with drain 16. An additional electrode (not shown), known as a body electrode is coupled with body 12, and is further connected to source electrode 22 such that there is no voltage difference between source electrode 22 and the body electrode. Thereby, MOSFET 10 becomes a three terminal device (i.e., the source, drain and gate terminals). In the following description and in the rest of this application, the body electrode is ignored.

Dielectric layer 18 insulates gate electrode 20 from all other components of MOSFET 10. A voltage, V_{gs}, is applied between gate electrode 20 and source electrode 22 (this action is also referred to as applying a voltage to gate electrode 20), thereby producing an electric field underneath gate electrode 20. At the region of body 12 just below the dielectric layer 18 and gate electrode 20 the produced field is directed normal to gate electrode 20. That is, when voltage V_{gs} is applied to gate electrode 20, which is a conducting planar surface, gate electrode 20 produces a planar normal directed electric field. As the portion of body 12 between source 14 and drain 16 does not exceed beyond the boundaries of gate electrode 20, the electric field within that portion of body 12 is normal to gate electrode 20 and to dielectric layer 18. The normal directed electric field is produced by a planar equipotential surface (i.e., gate electrode 20 when voltage V_{gs} is applied thereto).

The produced electric field repels free holes (i.e., positive charge carrier) from the region of body 12 beneath dielectric layer 18 and between source 14 and drain 16. Additionally, electrons from N-type source 14 and drain 16 are attracted into that region beneath dielectric layer 18. When a sufficient amount of electrons is gathered in that region, that region effectively becomes an N-type region connecting source 14 and drain 16. The region of body 12 between source 14 and drain 16 and adjacent to dielectric layer 18, which is inverted into an N-type region, is called the channel region.

In this manner, when a voltage, V_{ds}, is applied between drain electrode 24 and source electrode 22, current can flow therebetween. Thus, MOSFET 10 enables the modulation of current out of drain 16 (i.e., as electrons flow via the channel from source 14 to drain 16, the current is considered as flowing in the opposite direction) by applying a voltage between source electrode 22 and gate electrode 20. The electric (i.e., electrostatic) field produced beneath gate electrode 20 forms a channel between source electrode 22 and drain electrode 24, and hence the device is referred to as a field effect transistor or a FET for short.

The channel length L and the channel width W are both indicated in FIG. 1 and are determined during the fabrication process of MOSFET 10. In particular, the channel length is the distance between source 14 and drain 16, and the channel width is the width of body 12. The cutoff frequency of a FET device, is inversely proportional to the channel length. Furthermore, the current flowing out of drain electrode 24 is dependent on the width to length ratio (W:L) of the channel region. It is also noted that the dimensions of the FET device (e.g., channel width W and length L) are usually determined by photolithography techniques,

As can be seen in FIG. 1, MOSFET 10 is a lateral MOSFET in which current flows in the lateral (i.e., parallel to the wafer's surface) direction. Alternatively, a FET can have a vertical configuration in which the source and the drain are vertically ordered. In such a configuration, the channel length can be controlled by deposition techniques instead of the lithography techniques employed for a lateral FET. Vertical FETs are described for example in the following publications: U.S. Pat. No. 6,720,617 issued to the inventor of the current application; U.S. Pat. No. 6,797,553 issued to Adckisson et al., and entitled “Method for Making Multiple Threshold Voltage FET Using Multiple Work-Function Gate Materials”; a presentation titled “Vertical Field Effect Transistors” by Lothar Hollt, published at the second FORNEL workshop on nanoelectronics, Mar. 15 2006, of universitat der bundeswehr; and the article titled “Nanoscale Transistors-Just Around the Gate?” by Cory D. Cress, published in Science magazine Vol. 341, Jul. 12, 2013. These publications describe different configurations for vertical FETs in which the channel length is determined by known deposition techniques

One deposition technique known in the art is Atomic Layer Deposition (ALD). ALD is a thin film deposition technique based on the sequential use of a gas phase chemical process, usually between two gas precursors. A substrate surface is sequentially exposed to each precursor, and the sequential exposures are repeated for depositing a thin film. The chemistry of the ALD precursors is similar in the technique of Chemical Vapor Deposition (CVD), however in ALD the precursors are separately introduced to the substrate surface, thereby enabling better control of film growth. A purge gas (e.g., nitrogen or argon) is introduced to the ALD chamber after each precursor to remove excess precursor from the chamber before the next precursor is introduced. Thus, ALD consists of repeating the following characteristic steps: exposure of a first precursor, purging of the chamber, exposure of a second precursor for reactivating the surface for reacting with the first precursor, and purging the chamber again. Each reaction cycle adds an atomic or molecular monolayer of material to the surface, referred to as the growth per cycle. These steps are repeated until the desired film thickness is achieved. ALD is employed for depositing various material films such as metals, oxides and nitrides, and can be employed for example for depositing gate dielectrics for FETs.

ALD was used for epitaxial growth of silicon in US Patent Application Publication No. 2006/0267081A1 to Jun-Seuck Kim; for Doping in “Ultra-Shallow Junction Formation by Atomic Layer Doping” by Mitsumasa Koyanagi in Electrochemical Society Proceedings Volume 2001-2; and for Dielectrics in “High-k Dielectrics Grown by Atomic Layer Deposition: Capacitor and Gate Applications” by M.D. Groner and S. M. George in Interlayer Dielectrics for Semiconductor Technologies Murarka, Eizenberg and Sinha (Eds).

An electric field within a conductive body accelerates the free electrons (i.e., charge carriers) within the conductive body until all the excess charge is dispersed on the external surface of the conductive body and the electric field within the body is cancelled. Thus, when voltage is applied to a conductive body, the free electrons of the conductive body are dispersed along the external surface of the conductive body. It is noted that the electrons are dispersed such that the mutual repletion between electrons is decreased to a minimum. Thereby, at sharp edges of the conductive body, more electrons are concentrated per surface area than at flat areas of the conductive surface. Hence, the electric field at the edges of the conductive body is much stronger (i.e., more charge per surface area) as compared with the fiat areas. This phenomenon is referred to in the literature as the field edge effect. See H. S. Fricker “Why Does Charge Concentrate on Points?” Phys Educ., 24,(1989).

### BRIEF DESCRIPTION OF THE DRAWINGS

The disclosed technique will be understood and appreciated more fully from the following detailed description taken in conjunction with the drawings in which:;

FIG. 1 is a schematic illustration of a Metal-Oxide Semiconductor FET, constructed and operative as known in the prior art;

FIGS. 2A, 2B, and 2C are schematic illustrations of a vertical FET, constructed and operative in accordance with an embodiment of the disclosed technique; and

FIGS. 3A, 3B, 3C, 3D, 3E, 3F, 3G, 3H, 3I, 3J and 3K, are schematic illustrations of the steps for producing a vertical FET device, constructed and operative in accordance with another embodiment of the disclosed technique.

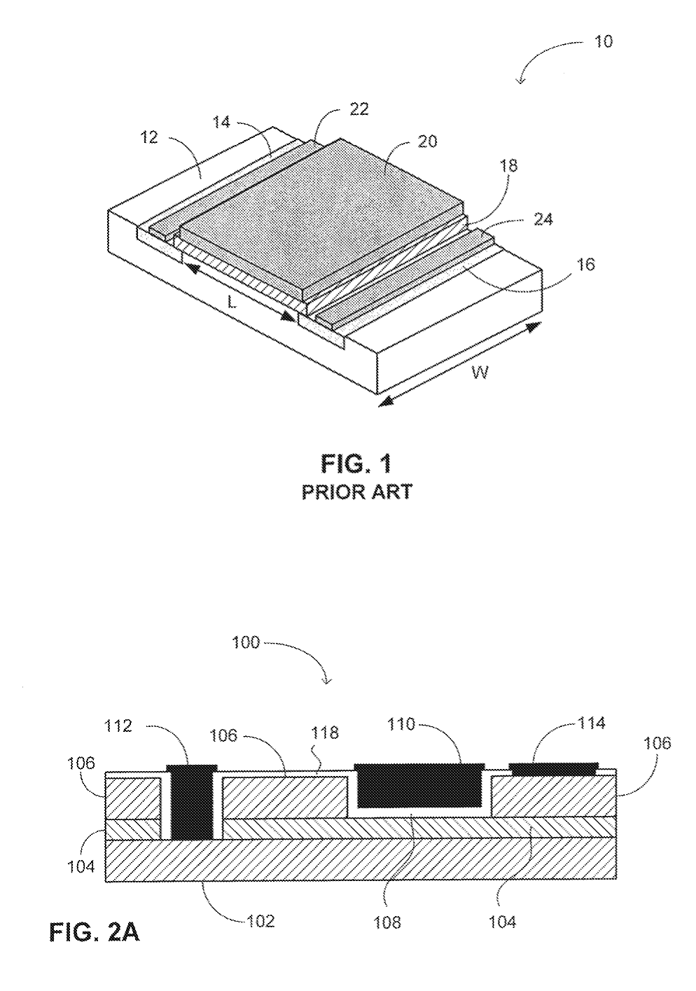

### DETAILED DESCRIPTION OF THE EMBODIMENTS

The disclosed technique overcomes the disadvantages of the prior art by providing a novel system and method for producing a vertical field effect transistor (VFET) including a source layer, a channel layer and a drain layer stacked on top of each other in that order, and further including a thin, conformal dielectric layer deposited on top of the channel layer through a cylindrical niche in the drain layer. Each one of a source electrode, a drain electrode and disc-shaped gate electrode, is coupled with the source layer, the drain layer, and the dielectric layer, respectively. The dielectric layer insulates the gate electrode from the channel layer and the drain layer.

According to the disclosed technique, an electric field is induced on a region of the channel layer by a voltage V_{gs} applied to the disc shaped gate electrode. The electric field at the edges of the gate electrode is stronger than the field adjacent to the flat surface of the electrode due to the field edge effect. The applied voltage Vgs produces a strong torus-shaped electric field within the channel layer that encircles the perimeter of the dielectric layer surrounding the gate electrode. The electric field within the channel layer attracts electrons from the source and the drain layers into the channel layer, thereby forming an N-type region within the channel layer (that is either a P-type or an I-type layer). The formed N-type region within the channel layer electrically connects the source layer to the drain layer. This N-type region within the channel layer is thus referred to as the channel region. The length of the channel region is essentially the thickness of the channel layer, and is determined by the grown thickness of the channel layer. The width of the channel region is determined by the length of the perimeter (i.e., and therefore by the diameter) of the disc shaped gate electrode.

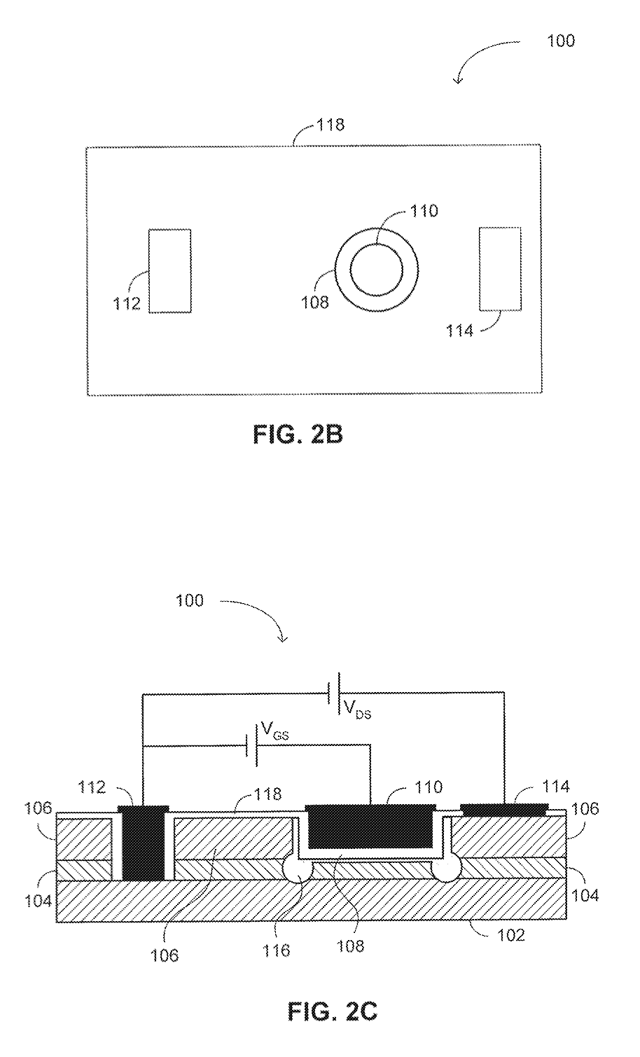

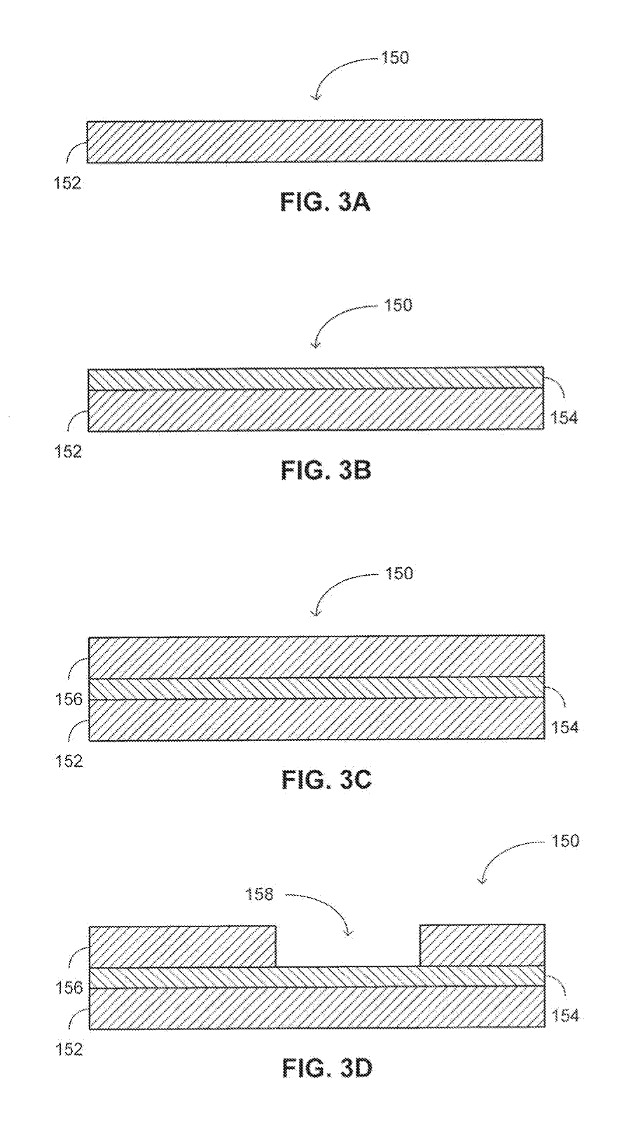

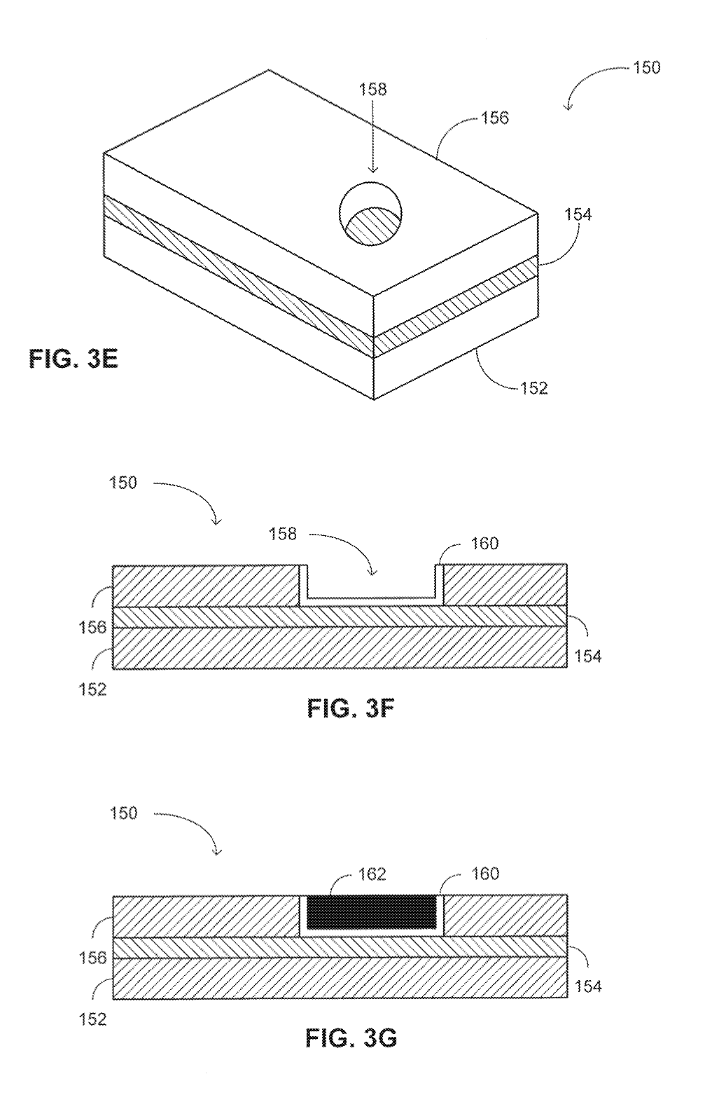

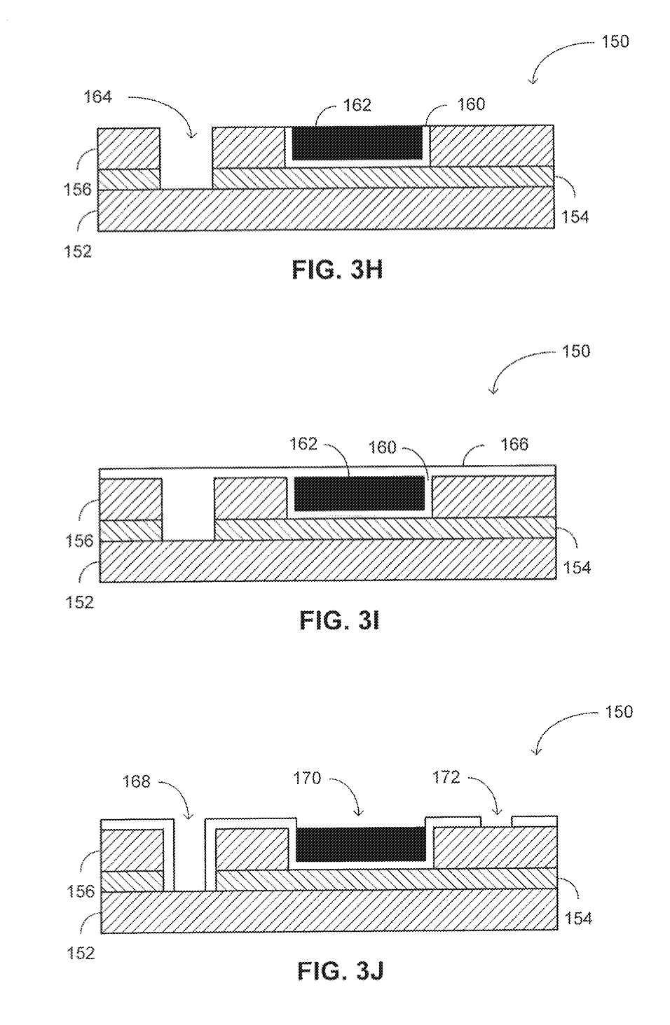

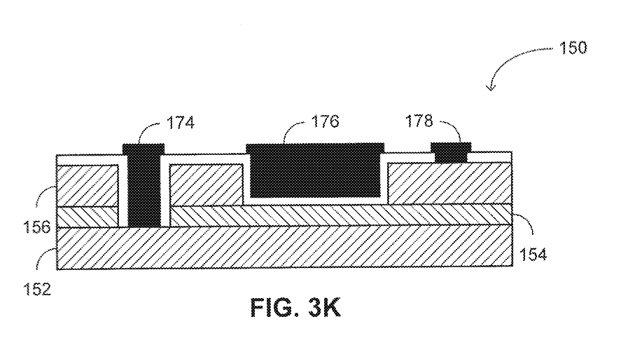

Below, the structure and operation of the vertical FET is described in FIGS. 2A-2C. Afterwards the production (i.e., fabrication) of the vertical FET is described in FIGS. 3A-3K. Reference is now made to FIGS. 2A, 2B and 2C which are schematic illustrations of a vertical FET, generally referenced 100, constructed and operative in accordance with an embodiment of the disclosed technique. FIG. 2A depicts a cross section of vertical FET 100, FIG. 2B depicts vertical FET 100 from a top view perspective, FIG. 2C depicts a cross section of vertical FET 100, also showing an electric field 116 produced around the gate dielectric (as described below).

Vertical FET 100 includes a source layer 102, a channel layer 104, a drain layer 106, a gate dielectric 108, a gate electrode 110, a source electrode 112, a drain electrode 114 and a field dielectric 118. Source layer 102, channel layer 104 and drain layer 106 constitute three layers of semiconductor material deposited on each other in that order. Herein each of source layer 102 and drain layer 106 is also referred to simply as source 102, and drain 106 respectively.

Gate Dielectric 108 is a thin layer, conformally deposited on the walls and bottom of a cylindrical niche etched in drain layer 106 down to channel layer 104. Gate electrode 110 is deposited into the cylindrical niche coated by gate dielectric 108 and thus takes the form of a cylinder (i.e., or a disc). Thereby, Gate dielectric 108 insulates gate electrode 110 other components of vertical FET 108 (e.g., it is insulated from channel layer 104 and from drain 106). Source electrode 112 is coupled with source 102. Drain electrode 114 is coupled with drain 106. Channel layer 104 is coupled between source 102 and drain 106 and is therefore also referred to herein below as interlayer 104. As will be detailed further herein below, the layered structure of channel layer 104 sandwiched between source and drain 106 forms back-to-back N-I and I-N junctions (or N-P and P-N junctions). Field dielectric 118 is deposited on top of source 102, drain 106 and gate dielectric 108 (i.e., except from the locations of the respective electrodes).

Source 102 and drain 106 are both formed of thin layers of N-type doped semiconductor material, whose thickness can be as little as a few nanometers (e.g., 5 nanometer). N-type doped layers are layers of semiconductor material that are doped with donor agents (not shown) like phosphorus or arsenic such that extra electrons are available. Channel layer 104 is formed from a thin I-type layer (i.e., a non-doped layer). Thus. vertical FET 100 includes two back-to-back N-I junctions. That is, FET 100 has an N-I-N configuration. In particular, FET 100 has an N-I-N vertically stacked configuration. Alternatively, channel layer 104 is made of a P-type layer doped with an acceptor agent such as boron (i.e., FET 100 has a N-P-N configuration). In a further alternative, source 102 and drain 106 are made of a P-type material, while channel layer 104 is made of either an I-type or an N-type material (i.e., FET 100 has either a P-I-P or a P-N-P configuration). In this case, the channel formed by the electric field will be a P-channel. The source and drain layers can be made from various materials, such as n-silicon, silicides of rare earth like yttrium silicide, or metals. The channel layer can be made from materials such silicon, germanium or a compound of SiGe.

Each of gate dielectric 108 and field dielectric 118 is formed from a dielectric (i.e. insulating) material, such as an oxide, a nitride, an oxinitride, a Hafnium oxide, a zirconium oxide, or a mixture thereof. For example, Field dielectric 118 is Si02. Gate electrode 110, source electrode 112 and drain electrode 114 are all made of conductive materials. For example, the material of gate electrode 110 can be poly-silicon, silicide or metal.

As with all FETs, for enabling a current to flow between drain 106 and source 102 (or vice versa, depending on the voltage difference between the electrodes), a channel (not referenced) must be formed via channel layer 104. The channel is formed by an electric field induced within channel layer 104 by applying a voltage V_{gs} to gate electrode 110. In particular, the voltage V_{gs} is applied between gate electrode 110 and source electrode 112 as can be seen in FIG. 2C. The channel is an N-type region formed within I-type channel layer 104 by the electric field that attracts electrons from source 102, channel layer 104 and from drain 106 into the channel (and in the case of a P-type channel layer, that attracts holes to the channel). The formed N-type region couples source 102 with drain 106, and acts as a channel (i.e., the channel region or simply the channel).

The thickness of channel layer 104 is only a few nanometers, and accordingly the exact channel length, as defined by the distance between source 102 and drain 106, is only a few nanometers. Such short channel lengths are achieved by employing thin film deposition techniques for depositing a thin layer of I-type (or P-type) material that serves as channel layer 104, on top of source 102. For example, and as detailed further below with reference to FIGS. 3A-3K, channel layer 104 is deposited by ALD.

As mentioned above, the Voltage V_{gs} applied between gate electrode 110 and source electrode 112 produces an electric field 116 (as shown in FIG. 2C) around gate electrode 110 and thus around gate dielectric 108. It is noted that the electric field is stronger at the edges of gate dielectric 108 due to the field edge effect. Electric field 116 induced within channel layer 104 attracts electrons from channel layer 104, source 102 and from drain 106. In case that channel layer 104 is made from a P-type material (and not an I-type material), field 116 also repels holes. When electric field 116 within a channel region of channel layer 104 is sufficiently strong, the attracted electrons transform a region of channel layer 104 into an N-type channel region connecting source 102 with drain 106. The minimum value of voltage V_{gs} applied to gate electrode 110, at which a channel between source 102 and drain 106 is formed via a region of channel layer 104, is referred to as the threshold voltage of vertical FET 100. The current flowing between drain 106 and source 102 can be modulated by the value of V_{gs} and of V_{ds}.

As electric field 116 is stronger at the edges of dielectric 108, for the same value of voltage V_{gs}, the depth of the channel region formed with channel layer 104 is larger at the edges of dielectric 108 than below the flat bottom surface of dielectric 108. Thus, at the threshold voltage value of V_{gs} a torus shaped channel is formed via channel layer 104, encircling the perimeter of dielectric 108. In the example shown in FIG. 2C, for the sake of simplicity, only the portion of electric field 116 that is induced within FET 100 is depicted. As mentioned above, the channel length is exactly defined by the thickness of channel layer 104, which is the distance between source 102 and drain 106. The width of the channel roughly corresponds to the perimeter of gate disc electrode 110. In other words, roughly speaking, the width of the channel can be estimated as the perimeter of gate dielectric 108 while its length is determined by the thickness of body 104. It is stressed that Nominal V_{gs} can be very low, preventing parasitic capacitance build-ups though still large to create the channel via the edge effect.

When a voltage V_{ds} (FIG. 2C) is applied between drain electrode 114 and source electrode 112 (i.e., while a voltage is applied to gate electrode 110 such that electric field 116 is produced and a channel is formed through channel layer 104), a current I_{ds} can flow from drain electrode 114 to source electrode 112. The magnitude of the flowing current I_{ds} is related to the channel width to length ratio W:L. Therefore, the channel length and width are important characteristic of a FET device. In the example set forth in FIGS. 2A 2C, the channel length corresponds to the thickness of channel layer 104, which is deposited by ALD techniques and therefore can be accurately and thinly deposited. The channel width is determined by the radius of gate dielectric 108. The o radius of gate dielectric 108 is determined by the radius of the cylindrical niche (in which gate dielectric 108 is deposited). The radius of the cylindrical niche is controlled by lithography and etching techniques used for producing the cylindrical niche. Alternatively, the cylindrical niche can be produced by other niche-making techniques, such as boring or ablating techniques.

Reference is now made to FIGS. 3A, 3B, 3C, 3D, 3E 3F, 3G, 3H, 3I, 3J and 3K, which are schematic illustrations of the steps for producing a vertical FET device, generally referenced 150, constructed and operative in accordance with another embodiment of the disclosed technique. With reference to FIG. 3A, source layer 152 is deposited. Source 152 is made of an N-type semiconductor material. That is, source 152 is made of a semiconductor material doped with an N-type agent or donor dopant that supplies free electrons. Source 152 is deposited by employing an ALD technique, and thereby the thickness of source 152 can be accurately controlled. The thickness of source 152 can range between a few nanometers to tens of nanometers. Source 152 is deposited on a crystalline substrate (not shown).

With reference to FIG. 3B, a channel layer 154 is deposited on top or source 152. Channel layer 154 is made of an I-type semiconductor material. That is, channel layer 154 is made of an intrinsic semiconductor material that is not doped. Channel layer 154 is deposited by employing an ALD technique, and thereby the thickness of channel layer 154 can be accurately controlled. The thickness of channel layer 154 can also range between a few nanometers to tens of nanometers. As mentioned above with reference to channel layer 104 of FIGS. 2A-2C, the thickness of channel layer 154 determines the length of the channel (not shown) of vertical FET 150.

With reference to FIG. 3C, drain layer 156 is deposited on top of channel layer 154. Drain 156 is made of an N-type semiconductor material. That is, drain 156 is made of a semiconductor material doped with an N-type agent or donor dopant that supplies free electrons. Drain 156 is deposited on top of channel layer 154 by employing an ALD technique. The thickness of drain 156 can also range between a few nanometers to tens of nanometers.

With reference to FIGS. 3D and 3E, a cylindrical niche 158 (i.e., blind hole 158) is etched in drain 156 down to channel layer 154. For better clarifying the drawing, in the example set forth in FIG. 3E, channel layer 154 is indicated by diagonal stripes. Cylindrical niche 158 is etched by known etching techniques, such as chemical, plasma or reactive ion etching. Alternatively, cylindrical niche 158 (and every other niche of the disclosed technique) is produced by other techniques for producing niches or bores, such as boring techniques or ablation techniques. The diameter of niche 158 can range between 5 nm to 100 nm.

With reference to FIG. 3F, a dielectric material 160 is conformally deposited within cylindrical niche 158. Specifically, dielectric 160 is deposited on the bottom of niche 158 (i.e., on top of channel layer 154) and on the side walls of niche 158 (i.e., dielectric 160 is surrounded by drain 156). Thereby, dielectric layer 160 forms a cylindrical niche there-within (i.e., dielectric 160 conforms to the shape of cylindrical niche 158 and thereby forms a cylindrical niche by itself). Dielectric 160 functions as a gate dielectric and serves to insulate the gate electrode deposited in the cylindrical niche formed by dielectric 162, as detailed below and as explained above.

With reference to FIG. 3G, a conductor pad 162 (i.e., functioning as a gate electrode as will be detailed below) is deposited within cylindrical niche 158. Conductor pad 162 is made of an electrically conductive material. Conductor pad 162 is insulated from the other components of FET 150 (e.g., insulated from channel layer 154 and from drain 156) by gate dielectric 160.

With reference to FIG. 3H, a niche 164 (i.e., blind hole 164) is etched in drain 156 and in channel layer 154 down to source 152. Niche 164 is etched by known etching techniques, such as chemical, plasma or reactive ion etching. Niche 164 can be box-shaped, cylindrical, or of any other shape. With reference to FIG. 3I, a field dielectric 166 is deposited on top of FET 150 such that field dielectric 166 fills niche 164 (FIG. 3H) and covers the top surface of drain 156, of gate dielectric 160 and of conductor pad 162.

With reference to FIG. 3J, niches are etched within field dielectric 166 (FIG. 3I) for a source, gate and drain electrodes. In particular, a source electrode niche 168 is etched through field dielectric 166 within niche 164 (FIG. 3H) down to source 152. A gate electrode niche 170 is etched through field dielectric 166 down to conductor pad 162 (FIG. 3H). A drain electrode niche 172 is etched through field dielectric 166 down to drain 156.

With reference to FIG. 3K, a source electrode 174, a gate electrode 176 and a drain electrode 178 are deposited within respective niches 168, 170 and 172 (FIG. 3J). Source electrode 174, gate electrode 176 and drain electrode 178 are made of conductive materials. In the example set forth in FIG. 3K, gate electrode 176 is in the shape of a flat cylinder (i.e., a disc) corresponding to the niche formed by gate dielectric 160 (i.e., filling the niche formed by gate dielectric 160). Each of source and drain electrodes 174 and 178 are drawn in the shape of a rectangular box but can take any geometrical shape. It is noted that gate electrode 176 includes the portion deposited within gate electrode niche 170 (FIG. 3J) and further includes conductor pad 162 (FIG. 3G) deposited within the cylindrical niche formed by gate dielectric 160.

The round perimeter of gate electrode 176 and of gate dielectric 160 (FIG. 3F) results in a homogenous electric field surrounding their perimeter and therefore, a homogenous channel within channel layer 154.

Source electrode 174, gate electrode 176 and drain electrode 178 serve as the three terminals of vertical FET device 150. Specifically, voltage applied between gate electrode 176 and source electrode 174 (V_{gs}) can form a channel via channel layer 154, and thereby voltage applied between drain electrode 178 and source electrode 174 (V_{ds}) would result in a current flowing out of drain electrode 178 (I_{ds}).

In case source electrode 174 is grounded, the voltage V_{gs} applied between gate electrode 176 and source electrode 174 is also referred as the voltage applied to gate electrode 176. During operation of vertical FET 150, the out flowing current I_{ds} is modulated by the voltage V_{gs} applied to gate electrode 176. As the thickness of channel layer 154 is very small (e.g., 5 nanometers), the voltage V_{gs} for forming a channel via channel layer 154 can be small as well (e.g., millivolts to tenth of a volt). Thus, parasitic capacitance within vertical FET 150 and within other components which may be positioned nearby (e.g., deposited above and/or below vertical FET 150 in a stacked configuration) is decreased. Additionally, as the channel is formed by a stronger electric field at the edges of gate dielectric 160 (i.e., the field is stronger due to the field edge effect), the threshold value for the voltage V_{gs} can be further decreased. Thereby, parasitic capacitance can also be further decreased.

It will be appreciated by persons skilled in the art that the disclosed technique is not limited to what has been particularly shown and described hereinabove. Rather the scope of the disclosed technique is defined only by the claims, which follow.

1. A vertical field effect transistor, comprising:
a source layer of a doped semiconductor material, said source layer being coupled with a source electrode;
a channel layer of a semiconductor material deposited on top of said source layer;
a drain layer of said doped semiconductor material deposited on top of said channel layer, said drain layer being coupled with a drain electrode; and
a gate dielectric conformity deposited within a cylindrical niche through said drain layer down to said channel layer such that said gate dielectric having a shape of said cylindrical niche, said gate dielectric being encircled by said drain layer, said gate dielectric being coupled with a gate electrode deposited within said cylindrical niche,
wherein when a threshold voltage is applied to said gate electrode, an electric field is induced within a channel region of said channel layer encircling said dielectric layer, thus forming a channel between said source layer and said drain layer, a length of said channel corresponding to a thickness of said channel layer and a width of said channel corresponding to a perimeter of said cylindrical niche.

2. The transistor of claim 1, wherein said thickness of said channel layer ranges between a few nanometers to tens of nanometers.

3. The transistor of claim 1, wherein said source layer and said drain layer are N-doped layers.

4. The transistor of claim 1, wherein said source layer and said drain layer are P-doped layers.

5. A method for producing a vertical field effect transistor, the method comprising the following procedure:
depositing a source layer of a doped semiconductor material;
depositing a channel layer of a semiconductor material on said source layer;
depositing a drain layer of said doped semiconductor material on said channel layer
producing a cylindrical niche in said drain layer down to said channel layer;
depositing a dielectric material within said cylindrical niche in a conformal manner, thereby producing a gate dielectric;
depositing an electrically conductive material within said cylindrical niche, thereby producing a conductor pad;
producing a niche in said drain layer and in said channel layer down to said source layer;
depositing a field dielectric on said transistor; such that said field dielectric fills said niche and covers said drain layer and said conductor pad;
producing a source electrode niche through said field dielectric within said niche down to said source layer;
producing a gate electrode niche through said field dielectric above said conductor pad down to said conductor pad;
producing a drain electrode niche through said field dielectric above said drain layer down to said drain layer;
depositing a source electrode within said source electrode niche;
depositing a gate electrode within said gate electrode niche; and
depositing a drain electrode within said drain electrode niche.
